(19) United States
(12) Patent Application Publication
(10) Pub. No.: US 2026/0039084 A1
(43) Pub. Date: Feb. 5, 2026

(54) LIGHT-EMITTING DEVICE

(71) Applicant: NICHIA CORPORATION, Anan-shi (JP)

(72) Inventor: Masatoshi NAKAGAKI, Komatsushima-shi (JP)

(21) Appl. No.: 19/269,019

(22) Filed: Jul. 14, 2025

(30) Foreign Application Priority Data
Jul. 30, 2024 (JP) 2024-123485

(51) Int. Cl. H01S 5/02315; H01S 5/02255

(52) U.S. Cl. CPC H01S 5/02315; H01S 5/02255

(57) ABSTRACT

A light-emitting device includes a base member, a frame member, a light source unit, a light-transmissive member, and a reflecting member. The frame member includes a first stepped portion. The frame member defines a recessed portion that penetrates from an inner lateral surface to an outer lateral surface of a part of the frame member with the recessed portion opening at an upper surface of the frame member. The light source unit is configured to emit laser beam in a normal direction to the upper surface of the base member. The light-transmissive member is disposed on an upper surface of the first stepped portion. The reflecting member is disposed on an upper surface of the light-transmissive member, and configured to reflect the laser beam transmitted through the light-transmissive member with an optical axis of the laser beam reflected by the reflecting member overlapping the recessed portion in top view.

### CROSS-REFERENCE TO RELATED APPLICATION

This application claims priority to Japanese Patent Application No. 2024-123485, filed on Jul. 30, 2024, the disclosure of which is hereby incorporated herein by reference in its entirety.

### TECHNICAL FIELD

The present disclosure relates to a light-emitting device.

### BACKGROUND

A light-emitting device is known, which includes a substrate having a mounting surface, a semiconductor laser element supported by the mounting surface, a first mirror member supported by the mounting surface and having a first reflecting surface facing obliquely upward, a cover having a facing surface facing the mounting surface of the substrate and an upper surface located on an opposite side to the facing surface, the cover being located above the semiconductor laser element and the first mirror member, and a second mirror member supported by the upper surface of the cover and having a second reflecting surface (for example, see Japanese Patent Publication No. 2024-018650).

### SUMMARY

An object of the present disclosure is to provide a light-emitting device that is less likely to block emitted laser beam.

A light-emitting device according to an embodiment of the present disclosure includes a base member, a frame member, a light source unit, a light-transmissive member, and a reflecting member. The frame member surrounds the base member and includes a first stepped portion. The frame member defines a recessed portion that penetrates from an inner lateral surface to an outer lateral surface of a part of the frame member with the recessed portion opening at an upper surface of the frame member. The light source unit is disposed on an upper surface of the base member with the frame member surrounding the light source unit. The light source unit is configured to emit laser beam in a normal direction to the upper surface of the base member. The light-transmissive member is disposed on an upper surface of the first stepped portion, and configured to transmit the laser beam. The reflecting member is disposed on an upper surface of the light-transmissive member, and configured to reflect the laser beam transmitted through the light-transmissive member with an optical axis of the laser beam reflected by the reflecting member overlapping the recessed portion of the frame member in top view.

An embodiment of the present disclosure can provide a light-emitting device that is less likely to block emitted laser beam.

### BRIEF DESCRIPTION OF DRAWINGS

FIG. 1 is a schematic perspective view exemplifying a light-emitting device according to a first embodiment.

FIG. 2 is a schematic exploded perspective view exemplifying the light-emitting device according to the first embodiment.

FIG. 3 is a schematic top view exemplifying the light-emitting device according to the first embodiment.

FIG. 4 is a schematic cross-sectional view taken along the cross-sectional line IV-IV in FIG. 3.

FIG. 5 is a schematic top view of the light-emitting device according to the first embodiment with a lid member removed.

FIG. 6 is a schematic top view of a frame member constituting a part of the light-emitting device according to the first embodiment.

FIG. 7 is a schematic partially enlarged cross-sectional view of the light-emitting device according to the first embodiment.

FIG. 8 is a schematic partially enlarged top view of the light-emitting device according to the first embodiment.

### DETAILED DESCRIPTION

Hereinafter, embodiments for carrying out the invention are described with reference to the drawings. Note that, in the following description, terms indicating a specific direction or position (for example, “upper”, “above”, “lower”, “below”, and other terms related to these terms) are used as necessary. However, these terms are used to facilitate understanding of the invention with reference to the drawings, and the technical scope of the present invention is not excessively limited by the meaning of these terms. For example, when the term “upper surface” is described, the invention does not always have to be used to face upward. Portions having the same reference signs appearing in a plurality of drawings indicate identical or equivalent portions or members. The term “on” in the present disclosure encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween.

In the present disclosure, polygons such as triangles and quadrangles, including shapes in which the corners of the polygon are rounded, chamfered, beveled, coved, and the like, are referred to as polygons. A shape obtained by processing not only the corners (ends of a side) but also an intermediate portion of the side is similarly referred to as a polygon. That is, a shape that is partially processed while leaving the polygon as the base is included in the interpretation of the “polygon” described in the present disclosure.

The same applies not only to polygons but also to words representing specific shapes such as trapezoids, circles, protrusions, and recessions. The same applies when dealing with each side forming that shape. That is, even when processing is performed on a corner or an intermediate portion of a certain side, the interpretation of “side” includes the processed portion. When a “polygon” or a “side” not partially processed is to be distinguished from a processed shape, the term “exact” is added to be described as, for example, “exact quadrangle”.

The following embodiments exemplify light-emitting devices and the like for embodying the technical concept of the present invention, and the present invention is not limited to the description below. The dimensions, materials, shapes, relative arrangements, and the like of constituent elements described below are not intended to limit the scope of the present invention to those alone but are intended to provide an example, unless otherwise specified. The contents described in one embodiment can be applied to any of the other embodiments and modified examples. The sizes, the positional relationship, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view.

### Embodiment

A light-emitting device according to the present disclosure includes a base member 210, a frame member 220 surrounding the base member 210 and having a stepped portion 225, a light source unit 230 disposed on an upper surface 210a of the base member 210 while being surrounded by the frame member 220, the light source unit 230 being configured to emit laser beam in a normal direction to the upper surface 210a of the base member 210, a light-transmissive member 240 disposed on an upper surface 225a of the stepped portion 225, and configured to transmit the laser beam, and a reflecting member 250 disposed on an upper surface 240a of the light-transmissive member 240, and configured to reflect the laser beam transmitted through the light-transmissive member 240. A recessed portion 220x penetrating from an inner lateral surface 220c to an outer lateral surface 220d of the frame member 220, and open toward an upper surface 220a of the frame member 220 is provided in a part of the frame member 220. An optical axis of the laser beam reflected by the reflecting member 250 overlaps the recessed portion 220x in top view.

### Light-Emitting Device 200

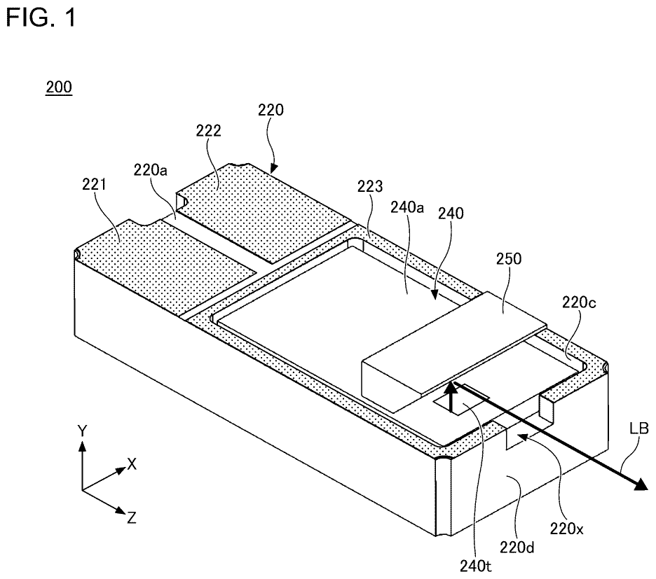

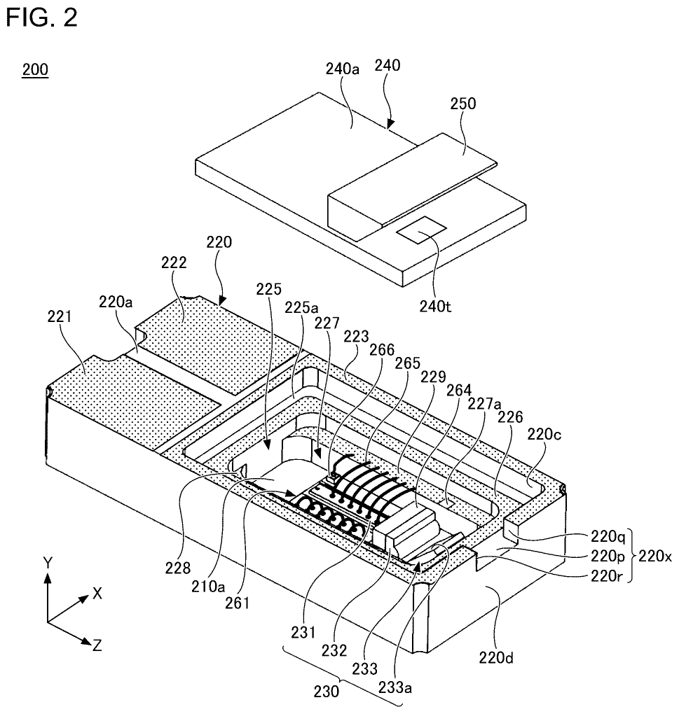

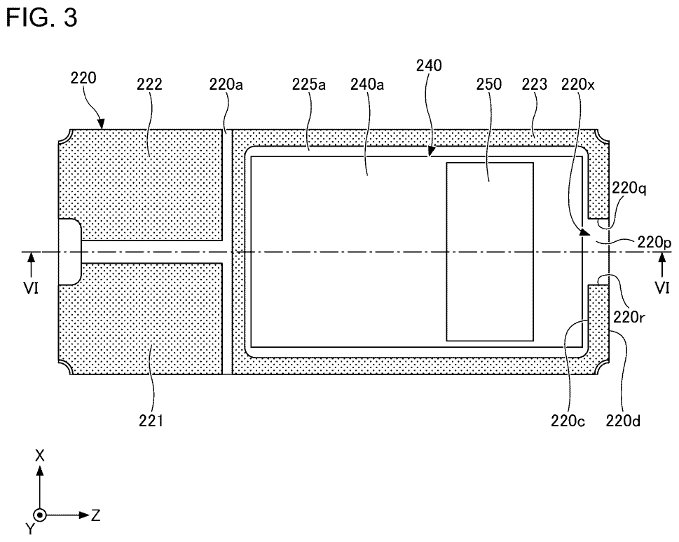

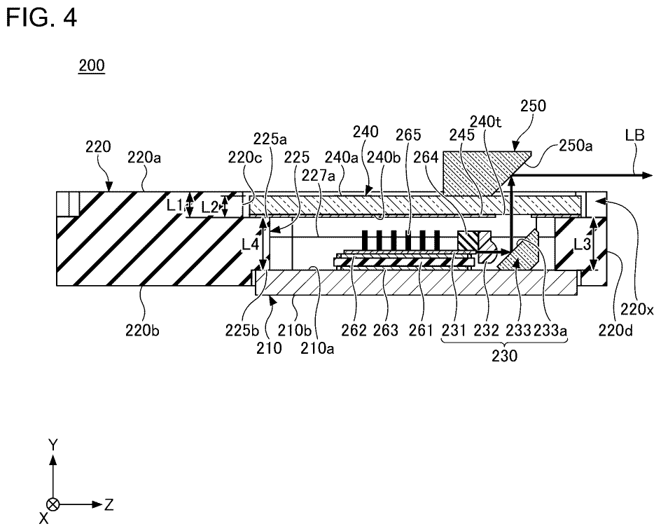

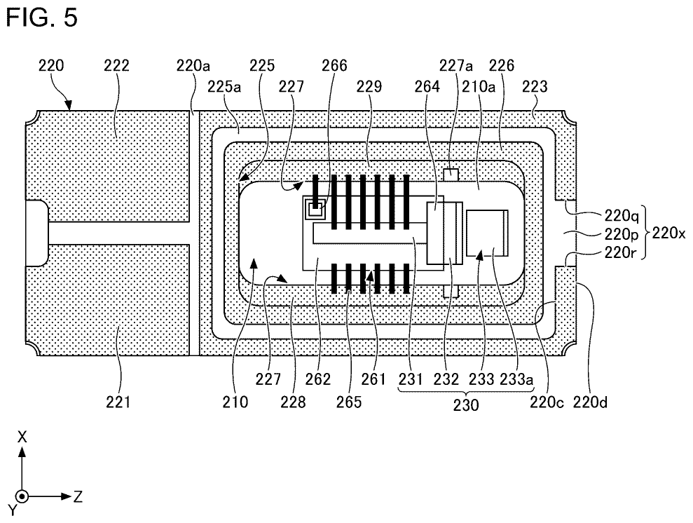

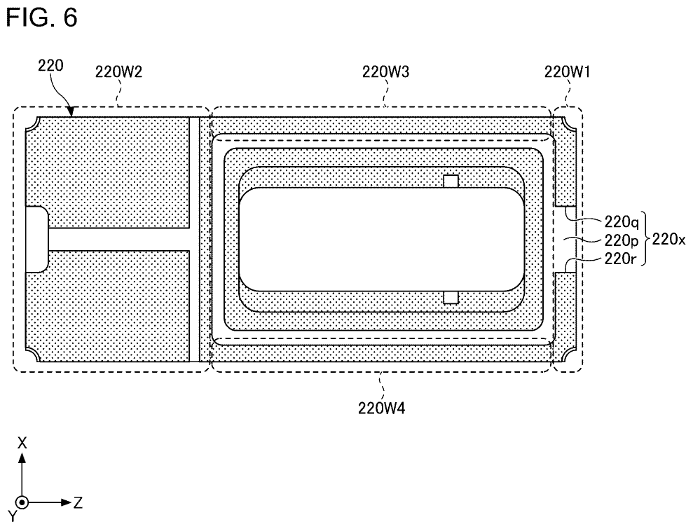

The light-emitting device 200 is described as an example of the light-emitting device according to the present disclosure. FIG. 1 is a schematic perspective view exemplifying a light-emitting device according to a first embodiment. FIG. 2 is a schematic exploded perspective view exemplifying the light-emitting device according to the first embodiment. FIG. 3 is a schematic top view exemplifying the light-emitting device according to the first embodiment. FIG. 4 is a schematic cross-sectional view taken along the cross-sectional line IV-IV in FIG. 3. FIG. 5 is a schematic top view of the light-emitting device according to the first embodiment with a lid member removed. FIG. 6 is a schematic top view of a frame member constituting the light-emitting device according to the first embodiment. In the schematic cross-sectional view illustrated in FIG. 4, some metal films are not illustrated.

In each of the drawings, an X-axis, a Y-axis, and a Z-axis orthogonal to one another are illustrated for reference as necessary. A direction parallel to the X-axis is referred to as an X direction, a direction parallel to the Y-axis is referred to as a Y direction, and a direction parallel to the Z-axis is referred to as a Z direction. In addition, in the X direction, a direction in which an arrow is directed is referred to as a +X direction, and a direction opposite to the +X direction is referred to as a −X direction. In the Y direction, a direction in which an arrow is directed is referred to as a +Y direction, and a direction opposite to the +Y direction is referred to as a −Y direction. In the Z direction, a direction in which an arrow is directed is referred to as a +Z direction, and a direction opposite to the +Z direction is referred to as a −Z direction. However, these directions do not limit the orientation of the light-emitting device during use, and any orientation of the light-emitting device may be employed. In addition, viewing an object from the +Y direction toward the −Y direction is referred to as top view.

The light-emitting device 200 according to the first embodiment includes the base member 210, the frame member 220, the light source unit 230, the light-transmissive member 240, and the reflecting member 250. In the example illustrated in FIGS. 1 to 6, the light-emitting device 200 further includes a submount 261, a lens support portion 264, wirings 265, and a protective element 266.

Each of the components of the light-emitting device 200 is described.

### Base Member 210

The base member 210 has the upper surface 210a and a lower surface 210b. The upper surface 210a and the lower surface 210b are, for example, flat surfaces. The upper surface 210a and the lower surface 210b are parallel to each other, for example. The term “parallel” is defined to allow a tolerance of ±5 degrees. The base member 210 has a rectangular outer shape in top view. This rectangular shape may be a rectangular shape with long sides and short sides. An outer shape of the base member 210 in top view does not have to be a rectangular shape. A rectangular shape may include a square shape unless specifically described as excluding a square shape.

The base member 210 can be made, for example, using metal as a main material. As the metal, for example, copper or a copper alloy can be used. The base member 210 may be formed of a main material other than metal, and may be formed of, for example, ceramic. The upper surface 210a of the base member 210 may be provided with a metal film.

### Frame Member 220

The frame member 220 includes the upper surface 220a, a lower surface 220b, one or a plurality of inner lateral surfaces 220c, and one or a plurality of outer lateral surfaces 220d. The frame member 220 has, for example, a rectangular frame shape in top view. The one or the plurality of inner lateral surfaces 220c of the frame member 220 are connected to the upper surface 220a, and extend downward from the upper surface 220a. The one or the plurality of outer lateral surfaces 220d of the frame member 220 are connected to the upper surface 220a and the lower surface 220b of the frame member 220. The frame member 220 surrounds the light source unit 230 in top view.

Metal films 221 and 222 electrically insulated from each other may be provided on the upper surface 220a of the frame member 220. For example, the metal film 221 and the metal film 222 are disposed side by side in the X direction while being spaced apart from each other. The metal films 221 and 222 have, for example, rectangular shapes having areas substantially equal to each other. A metal film 223 may be provided on the upper surface 220a of the frame member 220. The metal film 223 has, for example, a roughly rectangular frame shape. The metal film 223 surrounds the light source unit 230 in top view. As the metal films 221, 222, and 223, for example, a layered structure such as Ni/Au or Ti/Pt/Au can be used.

The frame member 220 has the stepped portion 225 (also referred to as a first stepped portion) including the upper surface 225a located above the upper surface 210a of the base member 210 and below the upper surface 220a of the frame member 220. The stepped portion 225 has an inner lateral surface that is connected to the upper surface 225a and extends downward. The upper surface 225a is connected to the one or the plurality of inner lateral surfaces 220c of the frame member 220. The upper surface 225a may be parallel to the upper surface 210a of the base member 210, for example. The inner lateral surface of the stepped portion 225 is connected to the upper surface 210a of the base member 210, for example. The stepped portion 225 may be provided along the inner lateral surface 220c of the frame member 220 in top view.

A metal film 226 may be provided on the upper surface 225a of the stepped portion 225. The metal film 226 has, for example, a rectangular frame shape. The metal film 226 surrounds the light source unit 230 in top view. The metal film 226 can be used when the frame member 220 is bonded to the light-transmissive member 240 via, for example, a metal adhesive. As the metal film 226, for example, the same as or similar to the metal film 221 can be used.

The stepped portion 225 may further have a lower surface 225b connected to the inner lateral surface of the stepped portion 225. The lower surface 225b may be a plane parallel to the upper surface 225a. The lower surface 225b is located above the lower surface 220b of the frame member 220. The lower surface 225b of the stepped portion 225 is bonded to the upper surface 210a of the base member 210. In the illustrated example, the frame member 220 further includes a lateral surface that is connected to the lower surface 225b and extends downward. The lateral surface is connected to the lower surface 220b of the frame member 220.

The frame member 220 may further include a second stepped portion 227 having an upper surface 227a located above the upper surface 210a of the base member 210 and below the upper surface 225a of the stepped portion 225. The second stepped portion 227 has an inner lateral surface that is connected to the upper surface 227a and extends downward. The upper surface 227a is connected to the inner lateral surface of the stepped portion 225. The upper surface 227a may be parallel to the upper surface 210a of the base member 210, for example. The inner lateral surface of the second stepped portion 227 is connected to the upper surface 210a of the base member 210, for example. A part of the inner lateral surface of the second stepped portion 227 may be connected to the inner lateral surface of the stepped portion 225.

The second stepped portion 227 may be provided along a part or all of the inner lateral surface of the stepped portion 225 in top view. In the illustrated example, two second stepped portions 227 facing each other in the X direction are provided along the inner lateral surface of the upper surface 225a of the stepped portion 225 in top view. A metal film 228 may be provided on the upper surface 227a of the second stepped portion 227 located in the −X direction. In addition, a metal film 229 may be provided on the upper surface 227a of the second stepped portion 227 located in the +X direction. The metal film 228 can be electrically connected to the metal film 221 through, for example, a via wiring. The metal film 229 can be electrically connected to the metal film 222 through, for example, a via wiring. As the metal films 228 and 229, for example, the same as or similar to the metal film 221 can be used.

In a part of the frame member 220, the recessed portion 220x penetrating from the inner lateral surface 220c to the outer lateral surface 220d of the frame member 220, and opening at the upper surface 220a of the frame member 220 is provided. The frame member 220 has a bottom surface 220p and wall surfaces 220q and 220r defining the recessed portion 220x. The wall surfaces 220q and 220r face each other. The bottom surface 220p may be a plane parallel to the upper surface 225a of the stepped portion 225. The bottom surface 220p may be coplanar with the upper surface 225a of the stepped portion 225. The wall surfaces 220q and 220r may be planes perpendicular to the bottom surface 220p. The wall surface 220q and the wall surface 220r may be parallel to each other. A distance between the bottom surface 220p of the recessed portion 220x and the upper surface 220a of the frame member 220 is, for example, 500 μm or more.

The frame member 220 may include two pairs of lateral wall portions facing each other. One pair of the lateral walls is lateral wall portions 220W1 and 220W2, and the other one pair is lateral wall portions 220W3 and 220W4. The lateral wall portion 220W1 and the lateral wall portion 220W2 face each other, and the lateral wall portion 220W3 and the lateral wall portion 220W4 face each other. The recessed portion 220x is preferably provided in only one of the lateral wall portions 220W1, 220W2, 220W3, and 220W4. In particular, the recessed portion 220x is preferably provided in the lateral wall portion 220W1 located on a side at which laser beam LB reflected by the reflecting member 250 reaches in top view. With this configuration, when the frame member 220 is held by a jig or the like, there is only one lateral wall portion that is difficult to held, while the number of lateral wall portions that can be held is increased, so that handling of the frame member 220 in a manufacturing process and the like is facilitated. In addition, the possibility that the laser beam LB is blocked can be reduced by the recessed portion 220x.

A notch, which does not penetrate from the inner lateral surface 220c to the outer lateral surface 220d of the frame member 220, is provided in the lateral wall portion 220W2 facing the lateral wall portion 220W1 provided with the recessed portion 220x. The notch is provided on a side farthest end in the −Z direction of the lateral wall portion 220W2 in top view. As a method for manufacturing the frame member 220, for example, arranging a plurality of frame members 220 in the X direction and the Z direction, monolithically forming the frame members 220, and then separating the individual frame members 220 is considered. In such a case, the notch is provided, so that two frame members 220 adjacent to each other in the Z direction can be easily separated from each other. In top view, the length of the notch in the X direction is equal to the length of the recessed portion 220x in the X direction.

The frame member 220 can be made using, for example, a material different from the material of the base member 210 as a main material. Examples of the main material for the frame member 220 include ceramic. For example, aluminum nitride, silicon nitride, aluminum oxide, or silicon carbide can be used as the ceramic.

### Light Source Unit 230

The light source unit 230 includes a semiconductor laser element 231, a lens 232, and a second reflecting member 233. The light source unit 230 does not have to include the lens 232 and/or the second reflecting member 233.

### Semiconductor Laser Element 231

In the illustrated example of the light-emitting device 200, one semiconductor laser element 231 is mounted. The light-emitting device 200 may be mounted with a plurality of semiconductor laser elements. The semiconductor laser element 231 has, for example, an outer shape of a rectangle in top view. A lateral surface including one of two short sides of this rectangle constitutes a light-emitting surface from which light of the semiconductor laser element 231 is emitted. Each of an upper surface and a lower surface of the semiconductor laser element 231 has a larger area than the light-emitting surface.

A metal film may be provided on the upper surface of the semiconductor laser element 231. This metal film is provided with, for example, wirings for conduction with other members.

Light (laser beam) emitted from the semiconductor laser element 231 spreads and forms an elliptical far field pattern (hereinafter, referred to as “FFP”) on a plane parallel to the light-emitting surface. The FFP indicates a shape and a light intensity distribution of emitted light at a position away from the light-emitting surface.

Based on the elliptical light emitted from the semiconductor laser element 231, a direction passing through the major axis of the elliptical shape is referred to as a fast axis direction of the FFP, and a direction passing through the minor axis of the elliptical shape is referred to as a slow axis direction of the FFP. The fast axis direction of the FFP in the semiconductor laser element 231 may coincide with a layering direction in which a plurality of semiconductor layers including an active layer of the semiconductor laser element 231 are layered.

Based on the light intensity distribution of the FFP of the semiconductor laser element 231, light having an intensity of 1/e² or greater relative to a peak intensity value is referred to as main light. In this light intensity distribution, an angle corresponding to the intensity of 1/e² is referred to as a divergence angle. The divergence angle of the FFP in the fast axis direction is greater than the divergence angle of the FFP in the slow axis direction. e is the base of a natural logarithm.

Furthermore, light passing through the center of the elliptical shape of the FFP, in other words, light having a peak intensity in the light intensity distribution of the FFP, is referred to as light traveling along an optical axis or light passing along an optical axis. Furthermore, an optical path of the light traveling through the center of the elliptical shape of the FFP is referred to as the optical axis of the light.

As the semiconductor laser element 231, for example, a semiconductor laser element that emits blue light can be used. The term “semiconductor laser element that emits blue light” refers to the use of a semiconductor laser element in which a light emission peak wavelength of emitted light is in a range from 405 nm to 494 nm. In addition, as the semiconductor laser element 231, a semiconductor laser element, in which a peak wavelength of emitted light is in a range from 430 nm to 480 nm, is preferably used. Examples of such a semiconductor laser element 231 include a semiconductor laser element including a nitride semiconductor. As the nitride semiconductor, for example, GaN, InGaN, AlGaN, or AlInGaN can be used.

The emission peak of the light to be emitted from the semiconductor laser element 231 does not have to be limited thereto. For example, the light to be emitted from the semiconductor laser element 231 may be visible light including green light, red light, and purple light, in addition to the blue light, having a wavelength outside the wavelength range described above, or may be ultraviolet light or infrared light.

### Lens 232

The lens 232 includes an incident surface on which light is incident, a lower surface connected to the incident surface, and a cylindrical surface from which the light incident from the incident surface is emitted. The cylindrical surface is connected to the lower surface. The incident surface opposes to the cylindrical surface. The incident surface and the lower surface of the lens 232 are, for example, flat surfaces. The incident surface is, for example, perpendicular to the lower surface. The cylindrical surface is a convex curved surface serving as a lens, and has a curvature on a YZ plane. The lens 232 may be, for example, a cylindrical lens having a uniform cross-sectional shape in the X direction.

The lens 232 may be formed of, for example, at least one light-transmissive material selected from the group consisting of glass, silicon, quartz, synthetic quartz, sapphire, and transparent ceramic. The lens 232 may include a portion used for attachment to another member, in addition to a portion serving as a lens.

### Second Reflecting Member 233

The second reflecting member 233 includes a lower surface, a reflecting surface 233a that reflects light, and a plurality of lateral surfaces connected to the reflecting surface 233a and the lower surface. In the light-emitting device 200 illustrated in the drawing, the lower surface, the reflecting surface 233a, and the plurality of lateral surfaces are flat surfaces. In side view, the second reflecting member 233 may have a triangular shape. In particular, in side view, the second reflecting member 233 may have a triangular shape with chamfered corners.

The plurality of lateral surfaces include two lateral surfaces opposing to each other with the reflecting surface 233a interposed therebetween. In addition, the plurality of lateral surfaces include one lateral surface connected to the two lateral surfaces opposing to each other with the reflecting surface 233a interposed therebetween. The two lateral surfaces opposing to each other with the reflecting surface 233a interposed therebetween may have areas equal to each other.

In the illustrated light-emitting device 200, the reflecting surface 233a has a rectangular shape. The reflecting surface 233a is inclined with respect to the lower surface of the second reflecting member 233. An inclination angle of the reflecting surface 233a with respect to the lower surface of the second reflecting member 233 is, for example, 45°, but is not limited to this angle and may be in a range from 30° to 60°, for example. When a specific angle of the inclination angle is described, a tolerance of ±5° from the specific angle is allowed for manufactured products in consideration of manufacturing accuracy.

The lower surface and the reflecting surface 233a may be curved surfaces or may be a mixture of flat surfaces and curved surfaces. In addition, the reflecting surface 233a does not have to be a rectangle as long as the reflecting surface 233a can reflect incident light in a desired direction.

Glass, metal, or the like can be used as a main material for forming the outer shape of the second reflecting member 233. The main material is preferably a heat-resistant material, and, for example, glass such as quartz or BK7 (borosilicate glass), metal such as aluminum, or Si can be used. The reflecting surface 233a may be provided with, for example, a metal or a dielectric multilayer film. Examples of the metal include Ag and Al. Examples of materials for the dielectric multilayer film include Ta₂O₅/SiO₂, TiO₂/SiO₂, and Nb₂O₅/SiO₂.

### Light-Transmissive Member 240

The light-transmissive member 240 includes the upper surface 240a, a lower surface 240b, and one or a plurality of lateral surfaces connected to the upper surface 240a and the lower surface 240b. The one or the plurality of lateral surfaces connect an outer edge of the upper surface 240a and an outer edge of the lower surface 240b. The light-transmissive member 240 is, for example, a rectangular parallelepiped or a cube. In this case, both the upper surface 240a and the lower surface 240b of the light-transmissive member 240 are rectangular in shape, and the light-transmissive member 240 has four rectangular lateral surfaces.

The light-transmissive member 240 is not limited to a rectangular parallelepiped or a cube. That is, the light-transmissive member 240 is not limited to a rectangular shape in top view, and can have any shape such as a circle, an ellipse, or a polygon.

The light-transmissive member 240 is formed of, for example, a light-transmissive material. Examples of the light-transmissive material include sapphire. Sapphire is a material with relatively high transmittance and relatively high strength. In addition to sapphire, for example, quartz, silicon carbide, or glass may be used as the light-transmissive material. The light-transmissive member 240 has a light transmission region 240t that transmits light. In top view, the light transmission region 240t has, for example, a rectangular shape, but the shape is not limited to this shape. The shape of the light transmission region 240t may be, for example, a circular shape or an elliptical shape. In the illustrated example, a light-shielding film 245 is provided in a region of the lower surface 240b of the light-transmissive member 240 except in a region through which light passes, thereby defining the light transmission region 240t. That is, the light-shielding film 245 surrounds the light transmission region 240t on the lower surface 240b of the light-transmissive member 240. The light-shielding film 245 may surround the light transmission region 240t on the upper surface 240a of the light-transmissive member 240. The light transmission region 240t preferably transmits 70% or more of laser beam.

The light-shielding film 245 reduces the possibility that stray light other than laser beam generated inside the light-emitting device 200 leaks to the outside of the light-emitting device 200. In a case in which a bonding member that is cured by irradiation with ultraviolet light or visible light is used to bond the reflecting member 250 to the upper surface of the light-transmissive member 240, the light-shielding film 245 can further reduce the possibility that the ultraviolet light or visible light emitted to the bonding member reaches the semiconductor laser element 231 when the bonding member is cured. The light-shielding film 245 can further reduce the possibility that the laser beam LB emitted to the outside of the light-emitting device 200 returns in a direction toward the light-emitting device 200 (hereinafter, referred to as return light) due to a factor such as diffuse reflection, and reaches the semiconductor laser element 231. Irradiation of the semiconductor laser element 231 with the ultraviolet light, the visible light, or the return light is reduced, and accordingly damage to the semiconductor laser element 231 can be reduced.

The light-shielding film 245 is preferably provided on the entire region of the lower surface of the light-transmissive member 240 other than the light transmission region 240t. The light-shielding film 245 provided in such a manner further reduces the possibility that the stray light leaks to the outside of the light-emitting device 200, and the possibility that the ultraviolet light, visible light, or the return light reaches the semiconductor laser element 231. The light-shielding film 245 can be formed of, for example, the same as or similar to the material of the metal film 221.

### Reflecting Member 250

The reflecting member 250 includes a lower surface, a reflecting surface 250a that reflects incident light, and a plurality of lateral surfaces connected to the reflecting surface 250a and the lower surface. In the illustrated light-emitting device 200, the lower surface, the reflecting surface 250a, and the plurality of lateral surfaces are flat surfaces.

The plurality of lateral surfaces include two lateral surfaces facing each other with the reflecting surface 250a interposed therebetween. In addition, the plurality of lateral surfaces include one lateral surface connected to the two lateral surfaces opposing to each other with the reflecting surface 250a interposed therebetween. The two lateral surfaces opposing to each other with the reflecting surface 250a interposed therebetween may have areas equal to each other.

In the illustrated light-emitting device 200, the reflecting surface 250a has a rectangular shape. The reflecting surface 250a is inclined with respect to the lower surface of the reflecting member 250. An inclination angle of the reflecting surface 250a with respect to the lower surface of the reflecting member 250 is, for example, 45°, but is not limited to this angle and may be in a range from 30° to 60°, for example.

The lower surface and the reflecting surface 250a may be curved surfaces or may be a mixture of flat surfaces and curved surfaces. In addition, the reflecting surface 250a does not have to be a rectangle as long as the reflecting surface 250a can reflect incident light in a desired direction.

The same as or similar to the material of the second reflecting member 233 can be used as a main material for forming the outer shape of the reflecting member 250. The reflecting surface 250a can be made using, for example, the same as or similar to the material of the reflecting surface 233a of the second reflecting member 233.

### Submount 261

The submount 261 is formed in a rectangular parallelepiped shape, for example, and has a lower surface, an upper surface, and one or a plurality of lateral surfaces. A part or all of the submount 261 may be formed of, for example, at least one selected from the group consisting of AlN, SiC, alumina, diamond, CuW, Cu, a layered structure of Cu/AlN/Cu, and a metal matrix compound (MMC). The MMC includes, for example, diamond and at least one selected from the group consisting of Cu, Ag, and Al. Alternatively, a part or all of the submount 261 may be formed of other general material.

The thermal conductivity of the submount 261 may be, for example, in a range from 10 [W/m·K] to 2500 [W/m·K]. With such a thermal conductivity, the submount 261 can efficiently transmit heat, which is generated from the semiconductor laser element 231 during driving, to the base member 210. The thermal expansion coefficient of the submount 261 may be, for example, in a range from 2×10⁻⁶ [l/K] to 2×10⁻⁵ [l/K]. Such a thermal expansion coefficient can reduce the possibility that the submount 261 is deformed due to heat applied when the semiconductor laser element 231 is bonded onto the submount 261 with a bonding material. The size of the submount 261 in the X direction is, for example, in a range from 1 mm to 3 mm. The size of the submount 261 in the Y direction is, for example, in a range from 0.1 mm to 0.5 mm. The size of the submount 261 in the Z direction is, for example, in a range from 1 mm to 6 mm.

A metal film having a thickness in a range from, for example, 0.5 μm to 10 μm may be formed on the upper surface and the lower surface of the submount 261 by, for example, plating. In the illustrated example, a metal film 262 is formed on the upper surface of the submount 261, and a metal film 263 is formed on the lower surface thereof. The metal film 262 is useful when the submount 261 and the semiconductor laser element 231 are bonded to each other with a bonding material and when power is supplied to the semiconductor laser element 231. The metal film 263 is useful when the submount 261 and the upper surface 210a of the base member 210 are bonded to each other with a bonding material. Providing the metal film 262 and the metal film 263 can improve the heat dissipation performance of the submount 261. As the metal films 262 and 263, for example, the same as or similar to the material of the metal film 221 can be used.

### Lens Support Portion 264

The lens support portion 264 is useful when the lens 232 is fixed to another member. The lens support portion 264 may be formed of, for example, ceramic selected from the group consisting of AlN, SiN, SiC, and alumina, or may be formed of at least one alloy selected from the group consisting of Kovar and CuW. The lens support portion 264 may be formed of Si, for example.

### Wiring 265

The wiring 265 is formed of a conductor having a linear shape with bonding portions at both ends thereof. In other words, the wiring 265 includes bonding portions, to be bonded to other components, at both ends of the linear portion. The wiring 265 is used for electrical connection between two components. As the wiring 265, for example, a metal wire can be used. Examples of the metal include gold, aluminum, silver, copper, and tungsten.

### Protective Element 266

The protective element 266 is a component for protecting a specific element such as the semiconductor laser element 231. For example, the protective element 266 is a component for hindering a specific element such as the semiconductor laser element 231 from being broken by an excessive current flowing through the specific element. As the protective element 266, for example, a Zener diode formed of Si can be used. For example, the protective element 266 may be a component for measuring temperature so that a specific element does not fail due to a temperature environment. A thermistor can be used as such a temperature measuring element. The temperature measuring element is preferably disposed near the light-emitting surface of the semiconductor laser element 231.

### Light-Emitting Device 200

The light-emitting device 200 is described below. A case in which the light source unit 230 includes the submount 261, the semiconductor laser element 231, the lens 232, and the second reflecting member 233 is described below as an example.

The submount 261 is disposed on the upper surface 210a of the base member 210. More specifically, the submount 261 is bonded to the upper surface 210a of the base member 210 via, for example, an adhesive on the lower surface side where the metal film 263 is provided. The semiconductor laser element 231 is directly or indirectly placed on the upper surface of the submount 261 disposed on the upper surface 210a of the base member 210. For example, the semiconductor laser element 231 is bonded via an adhesive to the metal film 262 provided on the upper surface of the submount 261. Examples of the adhesive used for this bonding include AuSn.

The semiconductor laser element 231 is disposed so that the light-emitting surface faces the same direction as one lateral surface of the submount 261. The light-emitting surface of the semiconductor laser element 231 may be, for example, parallel or perpendicular to one inner lateral surface 220c or one outer lateral surface 220d of the frame member 220. The semiconductor laser element 231 emits light traveling in the Z direction. The light emitted from the semiconductor laser element 231 is, for example, blue light. The light emitted from the semiconductor laser element 231 is not limited to blue light.

The semiconductor laser element 231 is electrically connected via the wiring 265 to the metal film 229 provided on the upper surface 227a of the second stepped portion 227 located in the +X direction. One end of the wiring 265 is bonded to a metal film provided on the upper surface of the semiconductor laser element 231. The light-emitting device 200 further includes a plurality of the wirings 265, for example. The plurality of wirings 265 include a wiring 265 in which one of both ends is bonded to the metal film 228 provided on the upper surface 227a of the second stepped portion 227 located in the +X direction, and the other end is bonded to the metal film 262 provided on the submount 261. With such a connection, power can be supplied to the semiconductor laser element 231 by applying a voltage between the metal film 221 and the metal film 222 provided on the upper surface 220a of the frame member 220.

The second stepped portion 227 is preferably provided at least at a position facing two lateral surfaces of the semiconductor laser element 231. This can shorten the wirings 265 that electrically connect the metal film 228 provided on the upper surface 227a of the second stepped portion 227 and the metal film 262 provided on the submount 261, and shorten the wirings 265 that electrically connect the metal film 229 provided on the upper surface 227a of the second stepped portion 227 and the metal film provided on the upper surface of the semiconductor laser element 231. Shortening the wirings 265 contributes to improvement in the electrical characteristics of the light-emitting device 200, and to downsizing of the light-emitting device 200. In addition, current can be easily supplied to the semiconductor laser element 231 via the metal films 228 and 229.

The lens 232 is directly or indirectly fixed to the submount 261. In the illustrated example, the lens 232 is fixed to the lens support portion 264 provided on the upper surface of the submount 261. The lens support portion 264 is provided on the upper surface of the submount 261 and supports the lens 232. The lens support portion 264 is provided in this manner, so that the lens 232 can be easily fixed to the submount 261. The semiconductor laser element 231 and the lens 232 are fixed to the same member by fixing the lens 232 to the submount 261. This can make the relative positional relationship between the semiconductor laser element 231 and the lens 232 less likely to be shifted.

The lens 232 is supported by the lens support portion 264 so that the incident surface faces the light-emitting surface of the semiconductor laser element 231, and the cylindrical surface faces the reflecting surface 233a of the second reflecting member 233. The focal point of the lens 232 substantially coincides with the center of a light emission point of the light-emitting surface of the semiconductor laser element 231. The lens 232 collimates, in the YZ plane, the laser beam LB emitted in the +Z direction from the light-emitting surface of the semiconductor laser element 231.

The second reflecting member 233 is disposed on the upper surface 210a of the base member 210. For example, the second reflecting member 233 is disposed on a metal film provided immediately below the second reflecting member 233. The lower surface of the second reflecting member 233 is located below the lower surface of the lens 232. In addition, the lowermost portion of the reflecting surface 233a is preferably located below the lower surface of the lens 232. With this structure, a larger amount of the light exiting from the cylindrical surface of the lens 232 can easily reach the reflecting surface 233a. The second reflecting member 233 includes a metal film on the lower surface thereof, and this metal film and the upper surface 210a of the base member 210 are bonded to each other via, for example, an adhesive. Examples of the adhesive used for this bonding include AuSn and Au paste.

The second reflecting member 233 is disposed beside the lens 232 on the upper surface 210a of the base member 210. The second reflecting member 233 is disposed on the opposite side to the semiconductor laser element 231 with the lens 232 interposed therebetween in the Z direction. The reflecting surface 233a of the second reflecting member 233 faces the direction of the cylindrical surface of the lens 232. The reflecting surface 233a of the second reflecting member 233 reflects the laser beam LB emitted from the light-emitting surface of the semiconductor laser element and passing through the lens 232, in the normal direction (+Y direction) to the upper surface 210a of the base member 210.

Although the case in which the light source unit 230 includes the submount 261, the semiconductor laser element 231, the lens 232, and the second reflecting member 233 has been described above, the light source unit 230 may have other configuration. For example, the light source unit 230 may be a vertical cavity surface emitting laser element provided on the upper surface 210a of the base member 210 directly or via the submount 261. Laser beam is emitted from the vertical cavity surface emitting laser element in the normal direction (+Y direction) to the upper surface 210a of the base member 210. Thus, when the vertical cavity surface emitting laser element is used as the light source unit 230, the second reflecting member 233 does not need to be separately provided, resulting in a decrease in the number of members.

The protective element 266 may be disposed on the upper surface of the submount 261, for example. In the illustrated example, one electrode of the protective element 266 is electrically connected via the wiring 265 to the metal film 229 provided on the upper surface 227a of the second stepped portion 227 located in the +X direction. The other electrode of the protective element 266 is electrically connected to the metal film 262 provided on the upper surface of the submount 261.

An outer peripheral portion of the upper surface 210a of the base member 210 is bonded to the lower surface 225b of the stepped portion 225 of the frame member 220. The frame member 220 surrounds the base member 210. In the illustrated example, in top view, the frame member 220 surrounds the light source unit 230, the submount 261, and the lens support portion 264 located on the base member 210. That is, the light source unit 230 is disposed on the upper surface 210a of the base member 210 while being surrounded by the frame member 220, and emits the laser beam LB in the normal direction to the upper surface 210a of the base member 210.

The light-transmissive member 240 is disposed on the upper surface 225a of the stepped portion 225 of the frame member 220 and transmits the laser beam LB. Specifically, the light-transmissive member 240 is supported by the upper surface 225a of the stepped portion 225 of the frame member 220, and is disposed above the semiconductor laser element 231 surrounded by the frame member 220. The outer peripheral portion of the lower surface 240b of the light-transmissive member 240 is bonded to, for example, the upper surface 225a of the stepped portion 225 of the frame member 220. For example, a metal film provided at the outer peripheral portion of the lower surface 240b of the light-transmissive member 240, and the metal film 226 provided on the upper surface 225a of the stepped portion 225 of the frame member 220 are bonded via AuSn or the like. The light-shielding film 245 may be used as a metal film when the light-transmissive member 240 and the upper surface 225a of the stepped portion 225 are bonded to each other. This can eliminate the need to separately provide a member for shielding light and a member for bonding. In this way, because the light-transmissive member 240 is disposed on the upper surface 225a of the stepped portion 225 of the frame member 220, when the light-transmissive member 240 is displaced during or after mounting, the displacement of the light-transmissive member 240 can be reduced because the movement of the light-transmissive member 240 is limited by the frame member 220.

In the normal direction to the upper surface 210a of the base member 210, a distance L1 from the upper surface 225a of the stepped portion 225 to the upper surface 220a of the frame member 220 is preferably longer than a distance L2 from the upper surface 225a of the stepped portion 225 to the upper surface 240a of the light-transmissive member 240. Thus, the upper surface 240a of the light-transmissive member 240 is disposed at a position recessed from the upper surface 220a of the frame member 220. With this structure, when the light-emitting device 200 is handled by suction, the contact position between a suction device and the light-emitting device 200 is located not on the upper surface 240a of the light-transmissive member 240, but on the upper surface 220a of the frame member 220, so that damage or contamination to the light-transmissive member 240 can be suppressed.

The lower surface 240b of the light-transmissive member 240 is bonded to the upper surface 225a of the stepped portion 225 of the frame member 220, thereby forming a space sealed by the base member 210, the frame member 220, and the light-transmissive member 240. The light source unit 230 may be disposed in the sealed space. This space may be a hermetically sealed space. When this space is hermetically sealed, for example, the possibility that organic matters and the like are collected on the light-emitting surface of the semiconductor laser element 231 constituting the light source unit 230 can be reduced.

In the normal direction to the upper surface 210a of the base member 210, a distance L3 from the upper surface 210a of the base member 210 to the bottom surface 220p of the recessed portion 220x is preferably equal to a distance L4 from the upper surface 210a of the base member 210 to the upper surface 225a of the stepped portion 225. Thus, the frame member 220 is easily manufactured, so that the manufacturing cost of the light-emitting device 200 can be reduced. In the above, the expression “the distance L3 and the distance L4 being equal” means that the difference between the two distances is less than 50 μm.

The reflecting member 250 is disposed on the upper surface 240a of the light-transmissive member 240, for example, via a bonding member. The reflecting surface 250a of the reflecting member 250 at least partially overlaps the light transmission region 240t of the light-transmissive member 240, and the reflecting surface 233a of the second reflecting member 233 in top view. The bonding member for fixing the reflecting member 250 may be, for example, a thermosetting resin that is cured by heating, or a photocurable resin that is cured by irradiation with ultraviolet light or visible light.

The reflecting member 250 reflects the laser beam LB transmitted through the light-transmissive member 240. Specifically, the laser beam LB reflected in the +Y direction by the reflecting surface 233a of the second reflecting member 233 is transmitted through the light transmission region 240t of the light-transmissive member 240, and reaches the reflecting surface 250a of the reflecting member 250. The laser beam LB having reached the reflecting surface 250a of the reflecting member 250 is reflected by the reflecting surface 250a, and the traveling direction of the laser beam LB is changed to the +Z direction.

When the bonding member for fixing the reflecting member 250 is formed, active alignment may be performed before the resin is cured. That is, when the bonding member is formed, the bonding member may be cured after the position and orientation of the reflecting member 250 are adjusted in such a manner that the reflecting surface 250a changes the traveling direction of the laser beam LB to the +Z direction in a state where the laser beam LB is emitted from the semiconductor laser element 231.

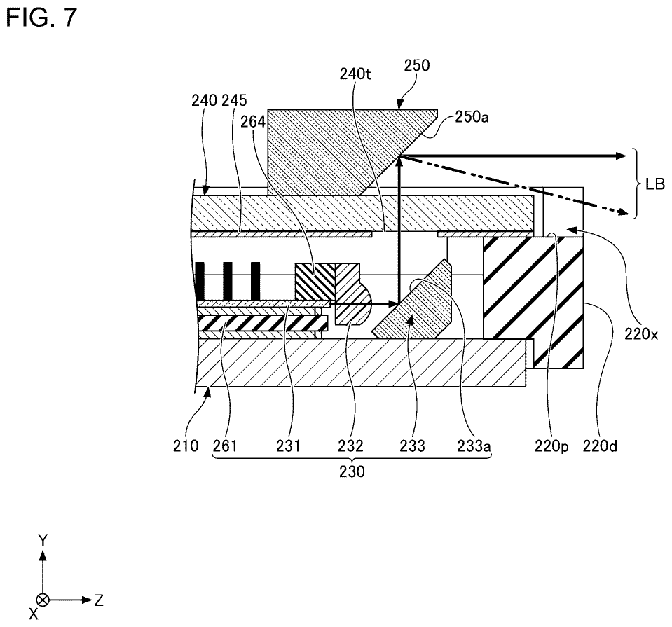

FIG. 7 is a schematic partially enlarged cross-sectional view of the light-emitting device according to the first embodiment, and illustrates a part of a cross-section taken along the cross-section line IV-IV in FIG. 3.

In FIG. 7, a solid-line arrow indicates an optical axis when the traveling direction of the laser beam LB reflected by the reflecting surface 250a is the +Z direction. A two-dot chain line arrow indicates an optical axis when the traveling direction of the laser beam LB reflected by the reflecting surface 250a is obliquely downward with respect to the +Z direction.

For example, the traveling direction of the laser beam LB reflected by the reflecting surface 250a may be obliquely downward with respect to the +Z direction due to manufacturing tolerances in assembling the components constituting the light-emitting device 200, an optical axis variation due to long-term use, an optical axis shift when the optical axis is changed to a desired position by active alignment of the reflecting member 250, or the like.

As illustrated in FIG. 7, in the light-emitting device 200, the recessed portion 220x is provided in the frame member 220. Thus, even when the traveling direction of the laser beam LB reflected by the reflecting surface 250a is obliquely downward with respect to the +Z direction, light passes through the recessed portion 220x and thus is unlikely to be blocked by the frame member 220. As a result, the amount of light to be emitted from the light-emitting device 200 can be increased.

In addition, when the light-transmissive member 240 is provided on the upper surface 225a of the stepped portion 225, the height of the light-transmissive member 240 and the reflecting member 250 from the upper surface 210a of the base member 210 is decreased compared to when the light-transmissive member 240 is provided on the upper surface 220a of the frame member 220. In this case, a distance between the optical axis of the laser beam reflected by the reflecting member 250 and the upper surface 220a of the frame member 220 is short, and when the traveling direction of the laser beam LB is obliquely downward with respect to the +Z direction, the laser beam LB is likely to be blocked by the frame member 220. Because the recessed portion 220x is provided, even when the traveling direction of the laser beam LB reflected by the reflecting surface 250a is obliquely downward with respect to the +Z direction, the laser beam LB passes through the recessed portion 220x and thus is unlikely to be blocked by the frame member 220. As a result, the amount of light emitted from the light-emitting device 200 can be increased.

In addition, in the light-emitting device 200, because the recessed portion 220x is provided in the frame member 220, in the main light to be emitted from the semiconductor laser element 231, light reflected by the reflecting surface 250a of the reflecting member 250 and traveling downward is unlikely to be blocked by the frame member 220. As a result, the utilization efficiency of the main light emitted from the semiconductor laser element 231 is improved, and the amount of light emitted from the light-emitting device 200 can be increased.

The recessed portion 220x preferably has such a depth that light traveling to the lowermost side in the main light emitted from the semiconductor laser element 231 does not hit the bottom surface 220p of the recessed portion 220x. Thus, the frame member 220 does not block the light, reflected by the reflecting surface 250a of the reflecting member 250 and traveling to the lowermost side, in the main light emitted from the semiconductor laser element 231. As a result, the utilization efficiency of the main light emitted from the semiconductor laser element 231 is further improved, and the amount of light to be emitted from the light-emitting device 200 can be further increased.

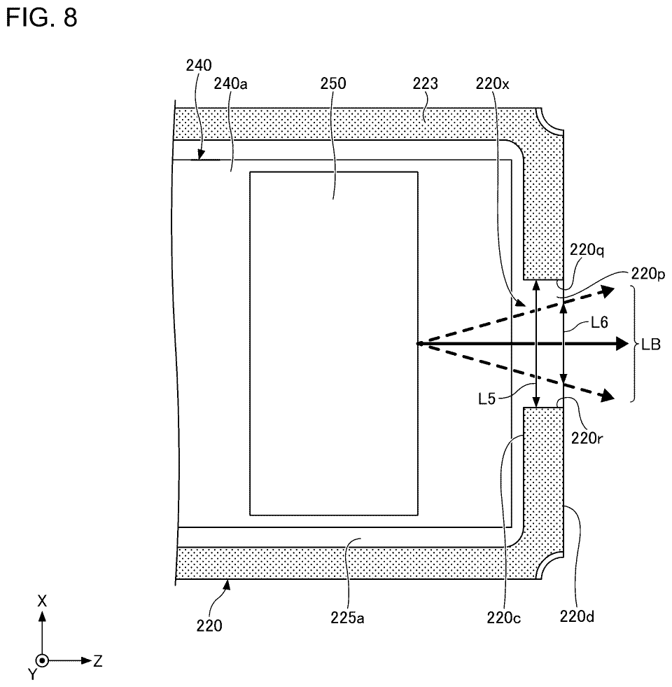

FIG. 8 is a schematic partially enlarged top view of the light-emitting device according to the first embodiment. In the laser beam LB illustrated in FIG. 8, a solid-line arrow indicates an optical axis, and two broken-line arrows indicate a range in which the main light emitted from the semiconductor laser element 231 spreads.

As illustrated in FIG. 8, the optical axis of the laser beam LB reflected by the reflecting surface 250a of the reflecting member 250 overlaps the recessed portion 220x in top view. Thus, in the main light emitted from the semiconductor laser element 231, light traveling in the leftward or rightward direction is unlikely to hit the wall surfaces 220q and 220r of the recessed portion 220x. As a result, the utilization efficiency of the main light emitted from the semiconductor laser element 231 is improved, and the amount of light emitted from the light-emitting device 200 can be increased.

In FIG. 8, a distance L5 between the wall surfaces 220q and 220r facing each other is preferably greater than a width L6 of the laser beam LB overlapping the bottom surface 220p of the recessed portion 220x in top view. Thus, in the main light emitted from the semiconductor laser element 231, the light traveling in the leftward or rightward direction does not hit the wall surfaces 220q and 220r of the recessed portion 220x. As a result, the utilization efficiency of the main light emitted from the semiconductor laser element 231 is further improved, and the amount of light emitted from the light-emitting device 200 can be further increased. The distance L5 can be, for example, 200 μm or more. A portion of the light emitted from the semiconductor laser element 231 that does not belong to the main light may hit the wall surfaces 220q and 220r of the recessed portion 220x and be reflected to become stray light. To reduce the influence of stray light, the wall surfaces 220q and 220r of the recessed portion 220x are preferably formed of a member having low light reflectivity.

Although the preferred embodiments and the like have been described in detail above, the invention is not limited to the above-described embodiments and the like, various modifications and substitutions can be made to the above-described embodiments and the like without departing from the scope described in the claims.

### REFERENCE SIGNS LIST

200 Light-emitting device; 210 Base member; 210a Upper surface; 210b Lower surface; 220 Frame member; 220a Upper surface; 220b Lower surface; 220c Inner lateral surface; 220d Outer lateral surface; 220p Bottom surface; 220q, 220r Wall surface; 220x Recessed portion; 220W1, 220W2, 220W3, 220W4 Lateral wall portion; 221, 222, 223, 226, 228, 229 Metal film; 225 Stepped portion; 225a Upper surface; 225b Lower surface; 227 Second stepped portion; 227a Upper surface; 230 Light source unit; 231 Semiconductor laser element; 232 Lens; 233 Second reflecting member; 233a Reflecting surface; 240 Light-transmissive member; 240a Upper surface; 240b Lower surface; 240t Light transmission region; 245 Light-shielding film; 250 Reflecting member; 250a Reflecting surface; 261 Submount; 262, 263 Metal film; 264 Lens support portion; 265 Wiring; and, 266 Protective element.

What is claimed is:

1. A light-emitting device comprising:
a base member;
a frame member surrounding the base member and including a first stepped portion, the frame member defining a recessed portion that penetrates from an inner lateral surface to an outer lateral surface of a part of the frame member with the recessed portion opening at an upper surface of the frame member;
a light source unit disposed on an upper surface of the base member with the frame member surrounding the light source unit, the light source unit being configured to emit laser beam in a normal direction to the upper surface of the base member;
a light-transmissive member disposed on an upper surface of the first stepped portion, and configured to transmit the laser beam; and
a reflecting member disposed on an upper surface of the light-transmissive member, and configured to reflect the laser beam transmitted through the light-transmissive member with an optical axis of the laser beam reflected by the reflecting member overlapping the recessed portion of the frame member in top view.

2. The light-emitting device according to claim 1, wherein in the normal direction, a distance from the upper surface of the first stepped portion to the upper surface of the frame member is longer than a distance from the upper surface of the first stepped portion to the upper surface of the light-transmissive member.

3. The light-emitting device according to claim 1, wherein
the frame member has a bottom surface and wall surfaces defining the recessed portion, the wall surfaces facing each other, and
a distance between the wall surfaces facing each other is greater than a width of the laser beam overlapping the bottom surface in top view.

4. The light-emitting device according to claim 3, wherein in the normal direction, a distance from the upper surface of the base member to the bottom surface of the recessed portion is equal to a distance from the upper surface of the base member to the upper surface of the first stepped portion.

5. The light-emitting device according to claim 1, wherein
the frame member includes two pairs of lateral wall portions facing each other, and
the recessed portion is defined in only one of the lateral wall portions.

6. The light-emitting device according to claim 1, wherein the light source unit includes a semiconductor laser element and a second reflecting member configured to reflect, in the normal direction, the laser beam emitted from a light-emitting surface of the semiconductor laser element.

7. The light-emitting device according to claim 6, wherein the frame member includes a second stepped portion having an upper surface located above the upper surface of the base member and below the upper surface of the first stepped portion,
a metal film is disposed on the upper surface of the second stepped portion, and
the semiconductor laser element is electrically connected to the metal film via a wiring.

8. The light-emitting device according to claim 7, wherein the second stepped portion is provided at least at positions respectively facing two lateral surfaces of the semiconductor laser element.

9. The light-emitting device according to claim 1, wherein
a hermetically sealed space is formed by the base member, the frame member, and the light-transmissive member, and
the light source unit is disposed in the hermetically space.
